(19) United States
(12) Patent Application Publication
(10) Pub. No.: US 2025/0003796 A1
(43) Pub. Date: Jan. 2, 2025

(54) MULTIPLE LIGHT BEAM OPTICAL FREQUENCY MONITORING ASSEMBLY

(71) Applicant: Lumentum Technology (UK) Limited, NORTHAMPTONSHIRE (GB)

(72) Inventors: Colin SMITH, Paignton (GB); Stuart CONLEY, Newton Abbot (GB); David DAVIES, Torquay (GB); Nick BROOKS, Paignton (GB); Samuel Justin JONES, Paignton (GB)

(21) Appl. No.: 18/478,202

(22) Filed: Sep. 29, 2023

Related U.S. Application Data
(60) Provisional application No. 63/511,059, filed on Jun. 29, 2023.

(51) Int. Cl. G01J 1/42

(52) U.S. Cl. CPC G01J 1/4257

(57) ABSTRACT

A multiple optical frequency monitoring assembly includes a first light source configured to generate a first light beam; a second light source configured to generate a second light beam; combiner optics configured to combine the first light beam and the second light beam into a combined light beam; a beam splitter configured to split the combined light beam into a monitored light beam and a reference light beam; an interferometer configured to receive the monitored light beam and output the monitored light beam as a monitored output light beam according to a resonant frequency response; filter optics configured to separate the monitored output light beam into two output beams; a detector configured to measure the two output beams; and a controller configured to tune the first light source and the second light source based on the two measured output beams and the reference light beam.

### CROSS-REFERENCE TO RELATED APPLICATION

This Patent Application claims priority to U.S. Provisional Patent Application No. 63/511,059, filed on Jun. 29, 2023, and entitled “MULTI-WAVELENGTH LOCKER.” The disclosure of the prior Application is considered part of and is incorporated by reference into this Patent Application.

### TECHNICAL FIELD

The present disclosure relates generally to a multiple light beam monitoring assembly and methods for monitoring multiple light beams with an interferometer.

### BACKGROUND

An interferometer may be used as a locker optics element. For example, an etalon, also known as a Fabry-Pérot interferometer, is a monolithic interferometric device containing two parallel reflecting surfaces. The etalon may include parallel mirrors and may be used as a narrow band frequency filter in laser applications (e.g., a resulting optical transmission or reflection of the etalon is periodic in frequency). Optical waves can pass through an optical cavity formed between the two parallel reflecting surfaces only when the optical waves are in resonance with the etalon. When inserted into a laser beam, the etalon acts as an optical resonator (cavity), where a transmissivity varies approximately periodically with an optical frequency (or wavelength). In resonance, reflections from the two parallel reflecting surfaces cancel each other via destructive interference. A highest reflection loss (e.g., a lowest transmissivity) occurs in anti-resonance. The transmissivity versus frequency relationship can be described with a frequency response (e.g., an etalon transfer function). An Airy function is one type of etalon transfer function. The etalon can therefore be used as an optical filter for tuning a frequency (or a wavelength) of a laser to lock the frequency of the laser at a desired frequency.

### SUMMARY

In some implementations, a multiple optical frequency monitoring assembly includes a first light source configured to generate a first light beam at a first optical frequency; a second light source configured to generate a second light beam at a second optical frequency different from the first optical frequency; combiner optics configured to combine the first light beam and the second light beam to generate a combined light beam; a beam splitter configured to split the combined light beam into a monitored light beam, comprising a first portion of the first light beam and a first portion of the second light beam, and a reference light beam, comprising a second portion of the first light beam and a second portion of the second light beam; an interferometer configured to receive the monitored light beam having a first incident intensity corresponding to the first portion of the first light beam and a second incident intensity corresponding to the first portion of the second light beam, wherein the interferometer is characterized by a resonant frequency response comprising a plurality of frequency ranges and a plurality of resonant peak frequencies at which a transmittivity of the interferometer is at a maximum transmission level, wherein the first optical frequency resides in a first frequency range of the plurality of frequency ranges and the second optical frequency resides in a second frequency range of the plurality of frequency ranges that is different from the first frequency range, wherein the interferometer is configured to output the monitored light beam as a monitored output light beam according to the resonant frequency response, wherein the monitored output light beam has first transmitted intensity corresponding to the first portion of the first light beam and a second transmitted intensity corresponding to the first portion of the second light beam, wherein the first transmitted intensity is based on the first incident intensity, the first optical frequency, and the resonant frequency response, and wherein the second transmitted intensity is based on the second incident intensity, the second optical frequency, and the resonant frequency response; filter optics configured to receive the monitored output light beam, and separate the first portion of the first light beam having the first transmitted intensity from the first portion of the second light beam having the second transmitted intensity, wherein the filter optics are configured to receive the reference light beam, and separate the second portion of the first light beam having a first reference intensity from the second portion of the second light beam having a second reference intensity; a detector arranged downstream from the filter optics, wherein the detector is configured to measure the first transmitted intensity, the second transmitted intensity, the first reference intensity, and the second reference intensity, generate a first difference value representative of a difference between the first transmitted intensity and the first reference intensity, and generate a second difference value representative of a difference between the second transmitted intensity and the second reference intensity; and a controller configured to tune the first optical frequency of the first light source based on the first difference value, and tune the second optical frequency of the second light source based on the second difference value.

In some implementations, a multiple optical frequency monitoring assembly includes a first light source configured to generate a first light beam at a first optical frequency; a second light source configured to generate a second light beam at a second optical frequency different from the first optical frequency; combiner optics configured to combine the first light beam and the second light beam to generate a combined light beam; an interferometer characterized by an initial frequency response and a complementary frequency response that is in anti-phase with the initial frequency response, wherein the interferometer is configured to receive the combined light beam, generate a first output light beam based on the combined light beam and the initial frequency response, and generate a second output light beam based on the combined light beam and the complementary frequency response, wherein the first output light beam has first transmitted intensity corresponding to a first portion of the first light beam and a second transmitted intensity corresponding to a first portion of the second light beam, wherein the second output light beam has third transmitted intensity corresponding to a second portion of the first light beam and a fourth transmitted intensity corresponding to a second portion of the second light beam, and wherein the first transmitted intensity is based on the first optical frequency and the initial frequency response, the second transmitted intensity is based on the second optical frequency and the initial frequency response, the third transmitted intensity is based on the first optical frequency and the complementary frequency response, and the fourth transmitted intensity is based on the second optical frequency and the complementary frequency response; filter optics configured to receive the first output light beam and the second output light beam, separate the first portion of the first light beam having the first transmitted intensity from the first portion of the second light beam having the second transmitted intensity, and separate the second portion of the first light beam having the third transmitted intensity from the second portion of the second light beam having the fourth transmitted intensity; a detector arranged downstream from the filter optics, wherein the detector is configured to measure the first transmitted intensity, the second transmitted intensity, the third transmitted intensity, and the fourth transmitted intensity, generate a first ratio value representative of a first ratio between the first transmitted intensity and the third transmitted intensity, and generate a second ratio value representative of a second ratio between the second transmitted intensity and the fourth transmitted intensity; and a controller configured to tune the first optical frequency of the first light source based on the first ratio value, and tune the second optical frequency of the second light source based on the second ratio value.

In some implementations, a multi-beam monitoring assembly includes a first light source configured to generate a first light beam with a beam property having a first property value; a second light source configured to generate a second light beam with the beam property having a second property value different from the first property value; combiner optics configured to combine the first light beam and the second light beam to generate a combined light beam; a beam splitter configured to split the combined light beam into a monitored light beam, comprising a first portion of the first light beam and a first portion of the second light beam, and a reference light beam, comprising a second portion of the first light beam and a second portion of the second light beam; an interferometer configured to receive the monitored light beam having a first incident intensity corresponding to the first portion of the first light beam and a second incident intensity corresponding to the first portion of the second light beam, wherein the interferometer is characterized by a resonant frequency response comprising a plurality of frequency ranges and a plurality of resonant peak frequencies at which a transmittivity of the interferometer is at a maximum transmission level, wherein the interferometer is configured to output the monitored light beam as a monitored output light beam according to the resonant frequency response, wherein the monitored output light beam has first transmitted intensity corresponding to the first portion of the first light beam and a second transmitted intensity corresponding to the first portion of the second light beam, wherein the first transmitted intensity is based on the first incident intensity, the first property value, and the resonant frequency response, wherein the second transmitted intensity is based on the second incident intensity, the second property value, and the resonant frequency response; filter optics configured to receive the monitored output light beam, and separate the first portion of the first light beam having the first transmitted intensity from the first portion of the second light beam having the second transmitted intensity, wherein the filter optics are configured to receive the reference light beam, and separate the second portion of the first light beam having a first reference intensity from the second portion of the second light beam having a second reference intensity, a detector arranged downstream from the filter optics, wherein the detector is configured to measure the first transmitted intensity, the second transmitted intensity, the first reference intensity, and the second reference intensity, generate a first difference value representative of a difference between the first transmitted intensity and the first reference intensity, and generate a second difference value representative of a difference between the second transmitted intensity and the second reference intensity; and a controller configured to tune the first property value of the first light source based on the first difference value, and tune the second property value of the second light source based on the second difference value.

### BRIEF DESCRIPTION OF THE DRAWINGS

FIG. 1 shows a multi-beam monitoring assembly according to one or more implementations.

FIG. 2A shows a multi-beam monitoring assembly according to one or more implementations.

FIG. 2B shows a resonant frequency response of a Fabry-Pérot interferometer.

FIG. 3A shows a multi-beam monitoring assembly according to one or more implementations.

FIG. 3B shows a resonant frequency response of a Michelson interferometer.

FIG. 4A shows a multi-beam monitoring assembly according to one or more implementations.

FIG. 4B shows frequency responses of a Mach-Zender interferometer.

### DETAILED DESCRIPTION

The following detailed description of example implementations refers to the accompanying drawings. The same reference numbers in different drawings may identify the same or similar elements.

A locker optics element, such as an interferometer, is typically used for single channel/frequency. In other words, the locker optics element is typically used for tuning a single light beam, produced by a single light source, at a desired optical frequency. However, for a system with a requirement for multiple channels (e.g., multiple light sources), multiple locker optics elements are needed (e.g., one locker optics element per channel) in order to tune and lock each light beam to a respective optical frequency. Accordingly, system complexity and cost increase as a number of channels increases.

For example, frequency detection for multiple channels may be multiplexed in time such that, at any instant, only one light beam passes through a locker optics element and/or one only one optical frequency can be detected. Dithering may be used to dither an intensity of an optical frequency to be monitored, and filtering may be used to filter a detector signal to a dither frequency. In some alternative cases, a tunable-optical-filter element may be inserted before a detector to dynamically select/scan the optical frequency to be monitored.

Some implementations provide a multiple optical frequency wavelength locker assembly with a two or more inputs/channels utilizing a single locker optics element. Multiple light beams provided as inputs to the locker optics element are combined before passing through the locker optics element and then are separated afterward such that each light beam can be monitored independently in order to provide feedback for two or more light sources. The multiple light beams may have different beam properties, such as different optical frequencies, different linear polarizations, or different spatial properties that enable the multiple light beams to be separated after passing through the locker optics element. The locker optics element may be configured to receive the multiple light beams at a same time such that each light beam continuously passes through the locker optics element at the same time. As a result, the locker optics element may be used to control multiple light sources in parallel. Accordingly, the locker optics element may be used passively and is self-contained, with no additional control mechanism (e.g., switching or multiplexing) or dithering required to tune the multiple light sources in parallel to lock the multiple light sources at respective optical frequencies.

Thus, the multiple optical frequency monitoring assembly may use a static, physical, optical demultiplexer and parallel detection to simultaneously monitor multiple optical frequencies without a need to insert dither tags. The multiple optical frequency monitoring assembly may include a single locker optics element for locking two or more frequencies in parallel based on detector feedback.

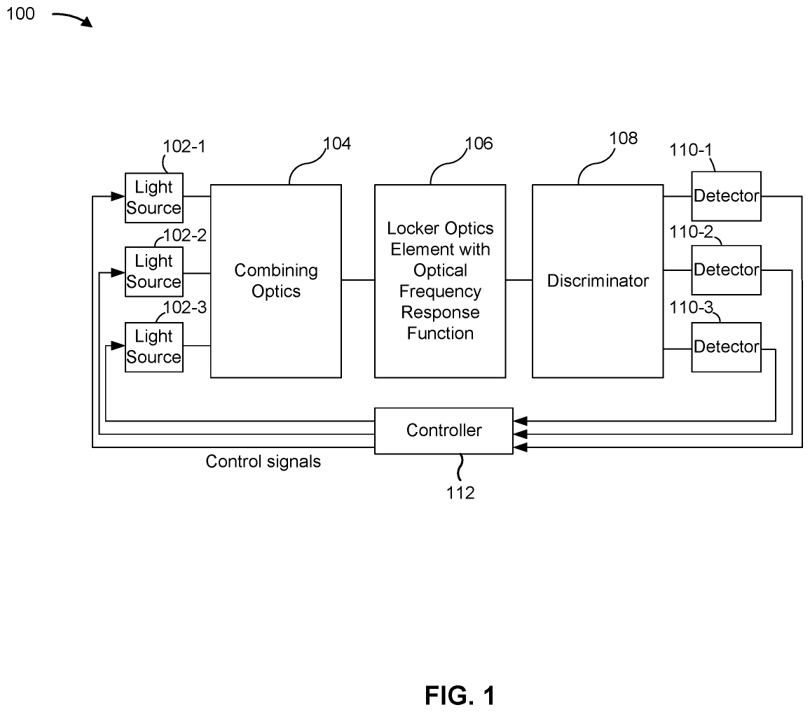

FIG. 1 shows a multi-beam monitoring assembly 100 according to one or more implementations. The multi-beam monitoring assembly 100 may be a multi-beam optical locker assembly or system that includes two or more input channels utilizing a single locker optics element, such as an interferometer. Each input channel may correspond to a different light source that is configured to generate a respective light beam (e.g., a respective laser beam) for transmission on the input channel. For example, the multi-beam monitoring assembly 100 may include a first light source 102-1 configured to generate a first light beam (e.g., a first laser beam) with a beam property having a first property value, a second light source 102-2 configured to generate a second light beam (e.g., a second laser beam) with the beam property having a second property value different from the first property value, and a third light source 102-3 configured to generate a third light beam (e.g., a third laser beam) with the beam property having a third property value different from the first property value and the second property value. Each light beam may be a collimated light beam. Thus, in some implementations, each light source may include a collimator.

In some implementations, the beam property may be an optical frequency such that the first property value is a first optical frequency f1, the second property value is a second optical frequency f2, and the third property value is a third optical frequency f3. Thus, the first, second, and third light beams may have different optical frequencies. Accordingly, the multi-beam monitoring assembly 100 may be a multiple optical frequency monitoring assembly.

In some implementations, the beam property may be a linear polarization such that the first property value is a first linear polarization, the second property value is a second linear polarization, and the third property value is a third linear polarization. Thus, the first, second, and third light beams may have different linear polarizations. For example, the second linear polarization may be orthogonal to the first linear polarization, and the third linear polarization may be at a different angle. In this case, the first, second, and third light beams may have different optical frequencies or a same optical frequency.

In some implementations, the beam property may be a spatial beam property such that the first property value is a first spatial value, the second property value is a second spatial value, and the third property value is a third spatial value.

The multi-beam monitoring assembly 100 may further include combining optics 104 that are optically coupled to the input channels for receiving the first light beam, the second light beam, and the third light beam. The combining optics 104 may be configured to combine the first light beam, the second light beam, and the third light beam onto a single optical path or single channel. The combined first light beam, second light beam, and third light beam may be referred to as a combined light beam.

The multi-beam monitoring assembly 100 may further include the locker optics element 106 that is arranged downstream from the combining optics 104 and optically coupled to the single channel to receive the combined light beam. The locker optics element 106 may be an interferometer, such as an etalon, a Michelson interferometer, or a Mach-Zehnder interferometer, that has one or more optical frequency response functions. An optical frequency response function may be referred to as a resonant frequency response or, simply, a frequency response. A transmittivity (and a reflectivity) of the locker optics element 106 depends on a property value of the beam property (e.g., optical frequency, polarization, or spatial property) of a received light beam relative to the optical frequency response function. In other words, the transmittivity (and the reflectivity) of the locker optics element 106 varies as a function of the property value. For example, the transmittivity (and the reflectivity) of the locker optics element 106 may vary as a function of optical frequency. An intensity of light transmitted through or output by the locker optics element 106 corresponds to the transmittivity of the locker optics element 106.

Each light beam of the combined light beam signal continuously and simultaneously passes through the locker optics element 106. Thus, an intensity of each light beam output from the locker optics element 106 depends on the optical frequency of that light beam.

The multi-beam monitoring assembly 100 may further include a discriminator 108 (e.g., an optical filter, such as a frequency filter, a polarizing filter, or a spatial filter, or a demultiplexer) arranged downstream from the locker optics element 106 and optically coupled to the single channel to receive the combined light beam output from the locker optics element 106. The discriminator 108 may be configured to separate the first light beam, the second light beam, and the third light beam from each other based on the beam property (e.g., based on optical frequency, linear polarization, or a spatial property), and provide the first light beam, the second light beam, and the third light beam to separate output channels (e.g., a first output channel, a second output channel, and a third output channel, respectively).

The multi-beam monitoring assembly 100 may further include multiple light detectors (e.g., photodetectors) that are arranged downstream from the discriminator 108 and are configured to measure an intensity of light. A light detector may be provided for each output channel and may correspond to a respective light source. In other words, each light detector may have a one-to-one correspondence with an input channel. For example, the multi-beam monitoring assembly 100 may include a first light detector 110-1 optically coupled to the first output channel and corresponding to the first light source 102-1, a second light detector 110-2 optically coupled to the second output channel and corresponding to the second light source 102-2, and a third light detector 110-3 optically coupled to the third output channel and corresponding to the third light source 102-3. Thus, the first light detector 110-1 may be configured to measure a transmitted intensity of the first light beam passed through the combining optics 104, the locker optics element 106, and the discriminator 108. The first light detector 110-1 may generate a first measurement signal representative of the transmitted intensity of the first light beam. The second light detector 110-2 may be configured to measure a transmitted intensity of the second light beam passed through the combining optics 104, the locker optics element 106, and the discriminator 108. The second light detector 110-2 may generate a second measurement signal representative of the transmitted intensity of the second light beam. The third light detector 110-3 may be configured to measure a transmitted intensity of the third light beam passed through the combining optics 104, the locker optics element 106, and the discriminator 108. The third light detector 110-3 may generate a third measurement signal representative of the transmitted intensity of the third light beam.

The multi-beam monitoring assembly 100 may further include a controller 112. In some implementations, the controller 112 or part of the controller 112 may be implemented in a detector that includes the first light detector 110-1, the second light detector 110-2, and the third light detector 110-3. The controller 112 may receive measured intensity values from the first light detector 110-1, the second light detector 110-2, and the third light detector 110-3 via the first, the second, and the third measurement signals, respectively. The controller 112 may also receive reference signals or reference intensities corresponding to the first, second, and third light beams. For example, additional light detectors may be used to measure the light intensities of the first, second, and third light beams at the input channels, and provide the measured light intensities as reference intensities of the first, second, and third light beams. Thus, each light beam may have a corresponding pair of intensities, including a transmitted intensity corresponding to an intensity at an output channel and a reference intensity corresponding to an intensity at an input channel. The controller 112 may include a processor or processing circuit configured to generate or calculate a difference value for each pair of intensities. A difference value may be calculated by subtracting the transmitted intensity from the reference intensity (or vice versa) or by calculating a ratio between the transmitted intensity and the reference intensity. Thus, the controller 112 may calculate a first difference value for the first light beam (e.g., by a subtraction calculation or a ratio calculation), calculate a second difference value for the second light beam, and calculate a third difference value for the third light beam.

The controller 112 may be configured to tune the first optical frequency of the first light source 102-1 based on the first difference value, tune the second optical frequency of the second light source 102-2 based on the second difference value, and tune the third optical frequency of the third light source 102-3 based on the third difference value. For example, controller 112 may generate a first control signal to be provided to the first light source 102-1 to tune the first optical frequency of the first light source 102-1 in order to drive the first difference value to a first predetermined value (e.g., a first target value). In some cases, the first predetermined value may be zero for the subtraction calculation or may be one for the ratio calculation, but the first predetermined value can be set to any desired value. Similarly, the controller 112 may generate a second control signal to be provided to the second light source 102-2 to tune the second optical frequency of the second light source 102-2 in order to drive the second difference value to a second predetermined value (e.g., a second target value). In some cases, the second predetermined value may be zero for the subtraction calculation or may be one for the ratio calculation, but the second predetermined value can be set to any desired value. Similarly, the controller 112 may generate a third control signal to be provided to the third light source 102-2 to tune the third optical frequency of the third light source 102-2 in order to drive the third difference value to a third predetermined value (e.g., a third target value). In some cases, the third predetermined value may be zero for the subtraction calculation or may be one for the ratio calculation, but the third predetermined value can be set to any desired value.

Accordingly, the controller 112 may be configured to lock the first optical frequency to a first target frequency, lock the second optical frequency to a second target frequency, and lock the third optical frequency to a third target frequency by monitoring corresponding pairs of intensities and tuning the optical frequencies of the first light source 102-1, the second light source 102-2, and the third light source 102-3 based on the monitoring. The multi-beam monitoring assembly 100 enables independent detection of each input channel (e.g., of each light source) to enable simultaneous frequency locking of each light source while using only one locker optics element. The locker optics element 106 may be used for multiple channels in a single device or assembly for frequency locking of multiple light beams. The multi-beam monitoring assembly 100 may allow the optical frequency of each light beam to be monitored continuously at the same time for frequency locking of each channel. In addition, the multi-beam monitoring assembly 100 may use a static, physical, optical demultiplexer and parallel detection to simultaneously monitor multiple frequencies without a need to insert dither tags. However, dither signals may still be used for other purposes.

Although not essential to the implementations describe herein and therefore not represented in the drawings or their descriptions, the output light of the light sources 102-1, 102-2, and 102-3 may be divided into two or more portions, with only one portion directed into the multi-beam monitoring assembly 100 for monitoring by a monitoring apparatus. In each case, the “beam” of one such portion is directed into the monitoring apparatus described herein, and the remaining portion(s) may be directed for useful output of a composite light source. The division of light into portions may occur for each discrete light source prior to being combined for monitoring, or the composite beam may be divided into portions between the combining optics 104 and the locker optics element 106. Alternatively, the discrete light sources 102-1, 102-2, and 102-3 may have multiple outputs at a same wavelength (or other primary property), where one such output would provide the light to be directed to the monitoring apparatus. For the purpose of the described implementations, the portion of the beam directed to the monitoring apparatus can be any portion of the total beam. However, typically the portion of the beam directed to the monitoring apparatus would be a minority portion (e.g., 5%, 1%, 0.25%, etc.) of the total beam generated by the light source, with a larger portion of the total beam being directed to the useful output. Therefore herein, when it is stated that a light source generates a light beam and that the generated light beam is combined, split, or otherwise manipulated in the monitoring apparatus, the manipulated light beam may not comprise the total beam generated by the light source.

As indicated above, FIG. 1 is provided as an example. Other examples may differ from what is described with regard to FIG. 1.

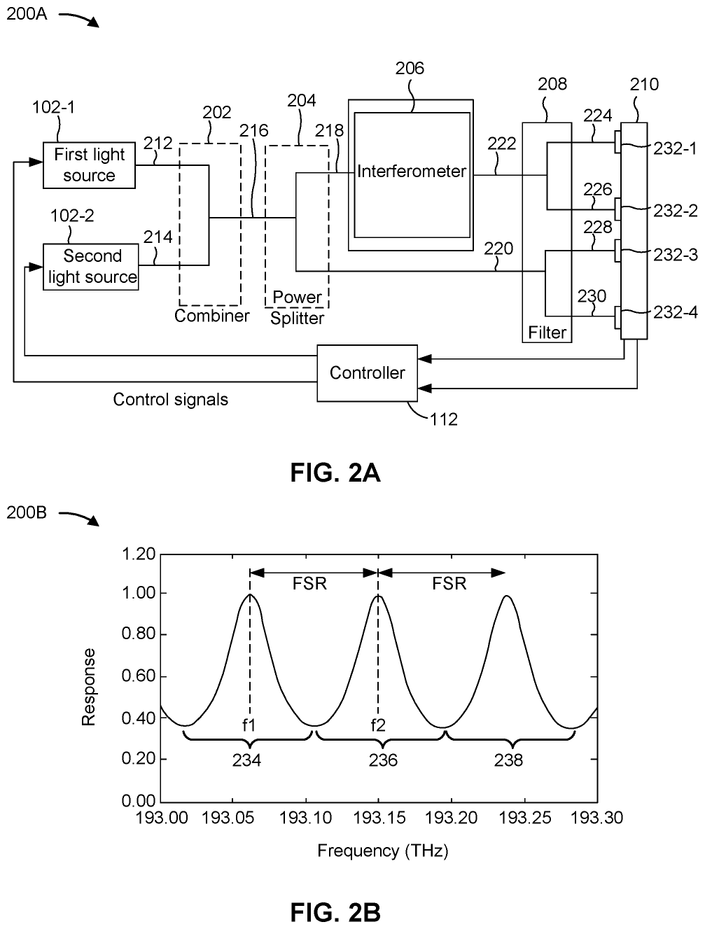

FIG. 2A shows a multi-beam monitoring assembly 200A according to one or more implementations. The multi-beam monitoring assembly 200A includes the first light source 102-1, the second light source 102-2, combiner optics 202, a power beam splitter 204, an interferometer 206, filter optics 208, a detector 210, and the controller 112. The multi-beam monitoring assembly 200A may include additional light sources for generating additional light beams that are provided to the combiner optics 202.

The first light source 102-1 may generate a first light beam 212 with a beam property having a first property value. The second light source 102-2 may generate a second light beam 214 with the beam property having a second property value different from the first property value. For example, as described above in connection with FIG. 1, the beam property may be an optical frequency, a linear polarization, or a spatial beam property. Thus, in some cases, the first light beam 212 and the second light beam 214 may have different optical frequencies and, in some cases, the first light beam 212 and the second light beam 214 may have a same optical frequency or substantially similar optical frequencies. Thus, in some implementations, the multi-beam monitoring assembly 200A may be a multiple optical frequency monitoring assembly configured for monitoring multiple optical frequencies in parallel.

The combiner optics 202 may combine the first light beam 212 and the second light beam 214 to generate a combined light beam 216. Thus, the first light beam 212 and the second light beam 214 are simultaneously included in the combined light beam 216.

The power beam splitter 204 may split the combined light beam 216 into a monitored light beam 218, comprising a first portion of the first light beam 212 and a first portion of the second light beam 214, and a reference light beam 220, comprising a second portion of the first light beam 212 and a second portion of the second light beam 214. In other words, the power beam splitter 204 may split the combined light beam 216 into two portions. In some implementations, the power beam splitter 204 may be a 50:50 power beam splitter such that an optical power of the monitored light beam 218 and an optical power of the reference light beam 220 are both 50% of an optical power of the combined light beam 216.

The interferometer 206 (e.g., a locker optics element) may receive the monitored light beam 218 having a first incident intensity corresponding to the first portion of the first light beam 212 and a second incident intensity corresponding to the first portion of the second light beam 214. The first incident intensity and the second incident intensity are light intensities at an input of the interferometer 206. The reference light beam 220 may bypass the interferometer 206. The interferometer 206 may be a Fabry-Pérot interferometer (e.g., an etalon), a Michelson interferometer, or a Mach-Zehnder interferometer. In this example, the interferometer 206 is an etalon. The interferometer 206 is characterized by a resonant frequency response that includes a plurality of frequency ranges and a plurality of resonant peak frequencies at which a transmittivity of the interferometer is at a maximum transmission level. Each frequency range of the plurality of frequency ranges may be defined by a respective pair of minima centered on a respective resonant peak frequency of the plurality of resonant peak frequencies. In other words, each frequency range may be defined by a different period of the resonant frequency response. For example, each resonant peak frequency of the plurality of resonant peak frequencies may be separated from an adjacent resonant peak frequency by a free spectral range (FSR) of the resonant frequency response. Likewise, each respective pair of minima may be separated in frequency by the free spectral range of the resonant frequency response. Thus, each frequency range of the plurality of frequency ranges may defined by the FSR of the resonant frequency response.

When the beam property is an optical frequency, such that the first light beam 212 has a first optical frequency f1 and the second light beam 214 has a second optical frequency f2 that is different from the first optical frequency f1, the first optical frequency f1 may reside in a first frequency range of the plurality of frequency ranges and the second optical frequency f2 may reside in a second frequency range of the plurality of frequency ranges that is different from the first frequency range.

The interferometer 206 may output the monitored light beam 218 as a monitored output light beam 222 according to the resonant frequency response. The monitored output light beam 222 may have a first transmitted intensity corresponding to the first portion of the first light beam 212 and a second transmitted intensity corresponding to the first portion of the second light beam 214. The first transmitted intensity and the second transmitted intensity are light intensities at an output of the interferometer 206. For example, the first transmitted intensity may be based on the first incident intensity, the first property value (e.g., the first optical frequency f1), and the resonant frequency response. The first portion of the first light beam 212 may be attenuated based on the first property value, where the first property value falls within the resonant frequency response. The second transmitted intensity may be based on the second incident intensity, the second property value (e.g., the second optical frequency f2), and the resonant frequency response. The first portion of the second light beam 214 may be attenuated based on the second property value, where the second property value falls within the resonant frequency response.

The filter optics 208 (e.g., a discriminator) may receive the monitored output light beam 222 from the interferometer 206, and separate the first portion of the first light beam 212 having the first transmitted intensity from the first portion of the second light beam 214 having the second transmitted intensity. The first portion of the first light beam 212 having the first transmitted intensity may be referred to as a first output beam 224. The first portion of the second light beam 214 having the second transmitted intensity may be referred to as a second output beam 226.

In addition, the filter optics 208 may receive the reference light beam 220 from the power beam splitter 204, and separate the second portion of the first light beam 212 having a first reference intensity from the second portion of the second light beam 214 having a second reference intensity. The second portion of the first light beam 212 having the first reference intensity may be referred to as a first reference beam 228. The second portion of the second light beam 214 having the second reference intensity may be referred to as a second reference beam 230.

In some implementations, the filter optics 208 may include at least one optical frequency filter configured to separate, by optical frequency, the first portion of the first light beam 212 having the first transmitted intensity from the first portion of the second light beam 214 having the second transmitted intensity, and separate, by optical frequency, the second portion of the first light beam 212 having the first reference intensity from the second portion of the second light beam 214 having the second reference intensity.

In some implementations, the filter optics 208 may include at least one polarization filter configured to separate, by polarization, the first portion of the first light beam 212 having the first transmitted intensity from the first portion of the second light beam 214 having the second transmitted intensity, and separate, by polarization, the second portion of the first light beam 212 having the first reference intensity from the second portion of the second light beam 214 having the second reference intensity.

In some implementations, the filter optics 208 may include at least one spatial filter configured to separate the first portion of the first light beam 212 having the first transmitted intensity from the first portion of the second light beam 214 having the second transmitted intensity, and separate the second portion of the first light beam 212 having the first reference intensity from the second portion of the second light beam 214 having the second reference intensity.

The detector 210 is arranged downstream from the filter optics 208, and may include multiple light detectors for measuring the light intensities of the first output beam 224, the second output beam 226, the first reference beam 228, and the second reference beam 230. For example, the detector 210 may include a first light detector 232-1 for measuring the first transmitted intensity, a second light detector 232-2 for measuring the second transmitted intensity, a third light detector 232-3 for measuring the first reference intensity, and a fourth light detector 232-4 for measuring the second reference intensity. The detector 210 may generate a first difference value representative of a difference between the first transmitted intensity and the first reference intensity, and may generate a second difference value representative of a difference between the second transmitted intensity and the second reference intensity. The detector 210 may provide the first difference value and the second difference value to the controller 112.

The controller 112 may generate control signals to tune the first property value of the first light source based on the first difference value, and to tune the second property of the second light source based on the second difference value. For example, the controller 112 may tune the first optical frequency f1 of the first light source 102-1 to drive the first difference value to a first predetermined value (e.g., a first target value), and the controller 112 may tune the second optical frequency f2 of the second light source 102-2 to drive the second difference value to a second predetermined value (e.g., a second target value).

In some implementations, the controller 112 may tune the first optical frequency f1 of the first light source 102-1 to drive the first optical frequency f1 to a first target optical frequency that corresponds to a first resonant peak frequency of the first frequency range, and may tune the second optical frequency f2 of the second light source 102-2 to drive the second optical frequency to a second target optical frequency that corresponds to a second resonant peak frequency of the second frequency range. In some cases, the first resonant peak frequency and the second resonant peak frequency may correspond to different peaks of the resonant frequency response.

In some implementations, the controller 112 may tune the first optical frequency f1 of the first light source 102-1 to drive a first ratio of the first incident intensity and the first transmitted intensity to a first target value, and may tune the second optical frequency f2 of the second light source 102-2 to drive a second ratio of the second incident intensity and the second transmitted intensity to a second target value.

As indicated above, FIG. 2A is provided as an example. Other examples may differ from what is described with regard to FIG. 2A.

FIG. 2B shows a resonant frequency response 200B of a Fabry-Pérot interferometer. Each resonant peak frequency of the plurality of resonant peak frequencies is separated from an adjacent resonant peak frequency by the FSR. Similarly, each respective pair of minima is separated in frequency by the FSR. The resonant frequency response 200B includes a plurality of frequency ranges 234, 236, and 238. Each frequency range may be defined by a respective pair of minima centered on a respective resonant peak frequency of the plurality of resonant peak frequencies. The first optical frequency f1 of the first light source 102-1 and the second optical frequency f2 of the second light source 102-2 may be provided in different frequency ranges. The different frequency ranges may be mutually exclusive.

As indicated above, FIG. 2B is provided as an example. Other examples may differ from what is described with regard to FIG. 2B.

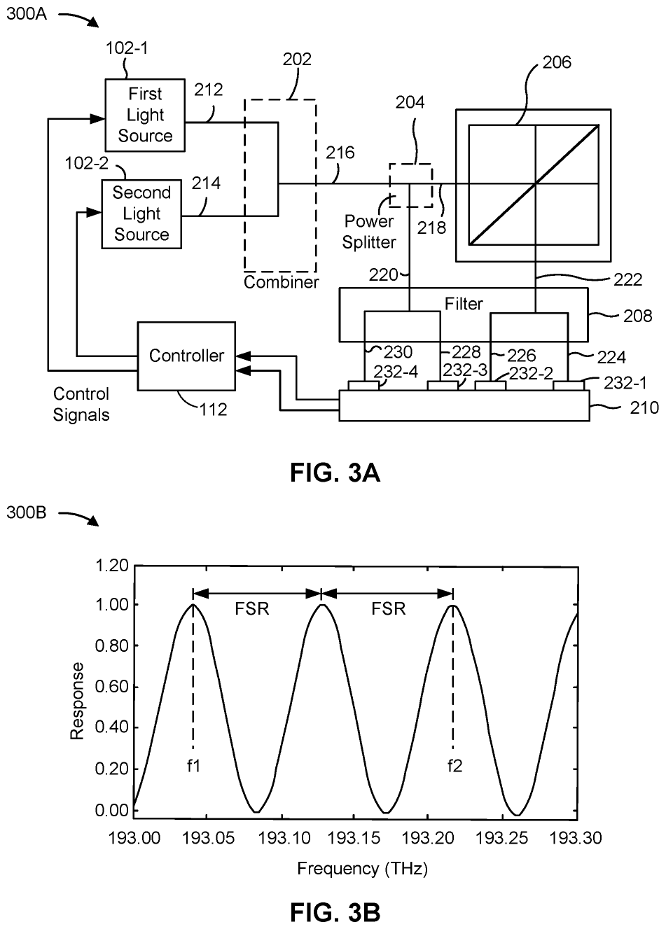

FIG. 3A shows a multi-beam monitoring assembly 300A according to one or more implementations. The multi-beam monitoring assembly 300A is similar to the multi-beam monitoring assembly 200A described in connection with FIGS. 2A and 2B, with the exception that the interferometer 206 is a Michelson interferometer.

As indicated above, FIG. 3A is provided as an example. Other examples may differ from what is described with regard to FIG. 3A.

FIG. 3B shows a resonant frequency response 300B of a Michelson interferometer corresponding to FIG. 3A. Different frequency ranges may be defined between different adjacent pairs of minima of the resonant frequency response 300B. Thus, the different frequency ranges may be mutually exclusive.

As indicated above, FIG. 3B is provided as an example. Other examples may differ from what is described with regard to FIG. 3B.

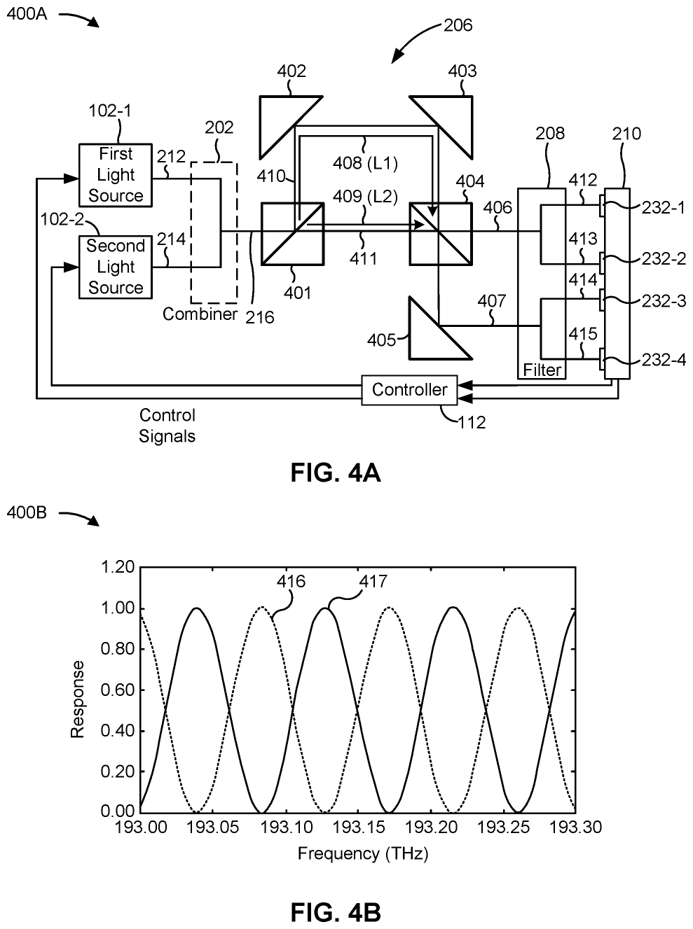

FIG. 4A shows a multi-beam monitoring assembly 400A according to one or more implementations. The multi-beam monitoring assembly 400A is similar to the multi-beam monitoring assembly 200A described in connection with FIGS. 2A and 2B, with the exception that the interferometer 206 is a Mach-Zender interferometer. As a result, the power beam splitter 204 is not present.

The first light source 102-2 may generate the first light beam 212 at the first optical frequency f1, and the second light source 102-2 may generate the second light beam 214 at the second optical frequency f2, which is different from the first optical frequency f1. The combiner optics 202 may combine the first light beam 212 and the second light beam 214 to generate the combined light beam 216.

The interferometer 206 in this example is characterized by an initial frequency response (e.g., a first frequency response) and a complementary frequency response (e.g., a second frequency response) that is in anti-phase with the initial frequency response. In other words, the initial frequency response and the complementary frequency response are 180° out of phase. The interferometer 206 may include a first beam splitter 401, a first reflector 402 (e.g., a first mirror), a second reflector 403 (e.g., a second mirror), a second beam splitter 404, and a third reflector 405 (e.g., a third mirror).

The interferometer 206 may receive the combined light beam 216, generate a first output light beam 406 based on the combined light beam 216 and the initial frequency response, and may generate a second output light beam 407 based on the combined light beam 216 and the complementary frequency response. For example, the first output light beam 406 may have a first transmitted intensity corresponding to a first portion of the first light beam 212 and a second transmitted intensity corresponding to a first portion of the second light beam 214. The second output light beam 407 may have a third transmitted intensity corresponding to a second portion of the first light beam 212 and a fourth transmitted intensity corresponding to a second portion of the second light beam 214. The first transmitted intensity may be based on the first optical frequency f1 and the initial frequency response, the second transmitted intensity may be based on the second optical frequency f2 and the initial frequency response, the third transmitted intensity may be based on the first optical frequency f1 and the complementary frequency response, and the fourth transmitted intensity may be based on the second optical frequency f2 and the complementary frequency response.

The first beam splitter 401 and the second beam splitter 404 may be separated by a first path 408 having a first path length L1 and a second path 409 having a second path length L2 that differs from first path length L1 by a path length difference AL. The path length difference AL defines the FSR of the initial frequency response and the complementary frequency response.

The first beam splitter 401 may split the combined light beam 216 into a first beam 410 and a second beam 411. For example, a first portion of the combined light beam 216 may be reflected by the first beam splitter 401 and a second portion of the combined light beam 216 may be passed through the first beam splitter 401 without reflection. Thus, the first beam 410 may correspond to the first portion of the combined light beam 216 that includes first components of the first light beam 212 and the second light beam 214. In addition, the second beam 411 may correspond to the second portion of the combined light beam 216 that includes second components of the first light beam 212 and the second light beam 214.

The first beam splitter 401 may direct the first beam 410 along the first path 408 and direct the second beam 411 along the second path 409. The second beam splitter 404 may receive the first beam 410 after being reflected by the first reflector 402 and the second reflector 403. The second beam splitter 404 may receive the second beam 411 directly from the first beam splitter 401. The second beam splitter 404 may generate the first output light beam 406 based on a first combination of the first beam 410 and the second beam 411. For example, a first portion of the first beam 410 may be reflected by the second beam splitter 404 to form part of the first output light beam 406, and a first portion of the second beam 411 may be passed through the second beam splitter 404 to form part of the first output light beam 406. Additionally, the second beam splitter 404 may generate the second output light beam 407 based on a second combination of the first beam 410 and the second beam 411. For example, a second portion of the first beam 410 may be passed through the second beam splitter 404 to form part of the second output light beam 407, and a second portion of the second beam 411 may be reflected by the second beam splitter 404 to form part of the second output light beam 407. The third reflector 405 may direct the second output light beam 407 to the filter optics 208.

The filter optics 208 may receive the first output light beam 406, and separate the first portion of the first light beam 212 having the first transmitted intensity from the first portion of the second light beam 214 having the second transmitted intensity. In other words, the filter optics 208 may separate the first output light beam 406 into a first detector beam 412 corresponding to the first portion of the first light beam 212, and a second detector beam 413 corresponding to the first portion of the second light beam 214.

Additionally, the filter optics 208 may receive the second output light beam 407, and separate the second portion of the first light beam 212 having the third transmitted intensity from the second portion of the second light beam 214 having the fourth transmitted intensity. In other words, the filter optics 208 may separate the second output light beam 407 into a third detector beam 414 corresponding to the second portion of the first light beam 212, and a fourth detector beam 415 corresponding to the second portion of the second light beam 214.

The detector 210, arranged downstream from the filter optics 208, may use light detectors 232-1, 232-2, 232-3, and 232-4 to measure the first transmitted intensity, the second transmitted intensity, the third transmitted intensity, and the fourth transmitted intensity, respectively. The detector 210 may generate a first ratio value representative of a first ratio between the first transmitted intensity and the third transmitted intensity, and may generate a second ratio value representative of a second ratio between the second transmitted intensity and the fourth transmitted intensity. The detector 210 may provide the first ratio value and the second ratio value to the controller 112.

The controller 112 may tune the first optical frequency f1 of the first light source 102-1 based on the first ratio value, and tune the second optical frequency f2 of the second light source 102-2 based on the second ratio value. For example, the controller 112 may adjust the first optical frequency f1 of the first light source 102-1 to drive the first ratio value to a first target value, and may adjust the second optical frequency f2 of the second light source 102-2 to drive the second ratio value to a second target value.

As indicated above, FIG. 4A is provided as an example. Other examples may differ from what is described with regard to FIG. 4A.

FIG. 4B shows frequency responses 400B of a Mach-Zender interferometer corresponding to FIG. 4A. The frequency responses 400B include an initial frequency response 416 and a complementary frequency response 417. The initial frequency response 416 includes a first plurality of frequency ranges and a first plurality of resonant peak frequencies at which a transmittivity of the Mach-Zender interferometer is at a maximum transmission level. The complementary frequency response 417 includes a second plurality of frequency ranges and a second plurality of resonant peak frequencies at which the transmittivity of the Mach-Zender interferometer is at the maximum transmission level.

The first optical frequency f1 of the first light source 102-1 described in connection with FIG. 4A may reside in a first frequency range of the first plurality of frequency ranges. The second optical frequency f2 of the second light source 102-2 described in connection with FIG. 4A may reside in a second frequency range of the first plurality of frequency ranges that is different from the first frequency range. Different frequency ranges may be defined by different adjacent pairs of minima of the initial frequency response and may be mutually exclusive.

As indicated above, FIG. 4B is provided as an example. Other examples may differ from what is described with regard to FIG. 4B.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of”' a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A multiple optical frequency monitoring assembly, comprising:
a first light source configured to generate a first light beam at a first optical frequency;
a second light source configured to generate a second light beam at a second optical frequency different from the first optical frequency;
combiner optics configured to combine the first light beam and the second light beam to generate a combined light beam;
a beam splitter configured to split the combined light beam into a monitored light beam, comprising a first portion of the first light beam and a first portion of the second light beam, and a reference light beam, comprising a second portion of the first light beam and a second portion of the second light beam;
an interferometer configured to receive the monitored light beam having a first incident intensity corresponding to the first portion of the first light beam and a second incident intensity corresponding to the first portion of the second light beam,
wherein the interferometer is characterized by a resonant frequency response comprising a plurality of frequency ranges and a plurality of resonant peak frequencies at which a transmittivity of the interferometer is at a maximum transmission level,
wherein the first optical frequency resides in a first frequency range of the plurality of frequency ranges and the second optical frequency resides in a second frequency range of the plurality of frequency ranges that is different from the first frequency range,
wherein the interferometer is configured to output the monitored light beam as a monitored output light beam according to the resonant frequency response,
wherein the monitored output light beam has first transmitted intensity corresponding to the first portion of the first light beam and a second transmitted intensity corresponding to the first portion of the second light beam,
wherein the first transmitted intensity is based on the first incident intensity, the first optical frequency, and the resonant frequency response, and
wherein the second transmitted intensity is based on the second incident intensity, the second optical frequency, and the resonant frequency response;
filter optics configured to receive the monitored output light beam, and separate the first portion of the first light beam having the first transmitted intensity from the first portion of the second light beam having the second transmitted intensity,
wherein the filter optics are configured to receive the reference light beam, and separate the second portion of the first light beam having a first reference intensity from the second portion of the second light beam having a second reference intensity;
a detector arranged downstream from the filter optics, wherein the detector is configured to measure the first transmitted intensity, the second transmitted intensity, the first reference intensity, and the second reference intensity, generate a first difference value representative of a difference between the first transmitted intensity and the first reference intensity, and generate a second difference value representative of a difference between the second transmitted intensity and the second reference intensity; and
a controller configured to tune the first optical frequency of the first light source based on the first difference value, and tune the second optical frequency of the second light source based on the second difference value.

2. The multiple optical frequency monitoring assembly of claim 1, wherein the controller is configured to tune the first optical frequency of the first light source to drive the first difference value to a first predetermined value, and
wherein the controller is configured to tune the second optical frequency of the second light source to drive the second difference value to a second predetermined value.

3. The multiple optical frequency monitoring assembly of claim 1, wherein the controller is configured to tune the first optical frequency of the first light source to drive the first optical frequency to a first target optical frequency that corresponds to a first resonant peak frequency of the first frequency range, and
wherein the controller is configured to tune the second optical frequency of the second light source to drive the second optical frequency to a second target optical frequency that corresponds to a second resonant peak frequency of the second frequency range.

4. The multiple optical frequency monitoring assembly of claim 1, wherein the controller is configured to tune the first optical frequency of the first light source to drive a first ratio of the first incident intensity and the first transmitted intensity to a first target value, and
wherein the controller is configured to tune the second optical frequency of the second light source to drive a second ratio of the second incident intensity and the second transmitted intensity to a second target value.

5. The multiple optical frequency monitoring assembly of claim 1, wherein the filter optics includes at least one optical frequency filter configured to separate, by optical frequency, the first portion of the first light beam having the first transmitted intensity from the first portion of the second light beam having the second transmitted intensity, and separate, by optical frequency, the second portion of the first light beam having the first reference intensity from the second portion of the second light beam having the second reference intensity.

6. The multiple optical frequency monitoring assembly of claim 1, wherein the filter optics includes at least one spatial filter configured to separate the first portion of the first light beam having the first transmitted intensity from the first portion of the second light beam having the second transmitted intensity, and separate the second portion of the first light beam having the first reference intensity from the second portion of the second light beam having the second reference intensity.

7. The multiple optical frequency monitoring assembly of claim 1, wherein each frequency range of the plurality of frequency ranges is defined by a free spectral range of the resonant frequency response.

8. The multiple optical frequency monitoring assembly of claim 1, wherein each frequency range of the plurality of frequency ranges is defined by a respective pair of minima centered on a respective resonant peak frequency of the plurality of resonant peak frequencies.

9. The multiple optical frequency monitoring assembly of claim 8, wherein each respective pair of minima is separated in frequency by a free spectral range of the resonant frequency response.

10. The multiple optical frequency monitoring assembly of claim 1, wherein each resonant peak frequency of the plurality of resonant peak frequencies corresponds to a different frequency range and is separated from an adjacent resonant peak frequency by a free spectral range.

11. The multiple optical frequency monitoring assembly of claim 1, wherein the interferometer is a Fabry-Pérot interferometer, a Michelson interferometer, or a Mach-Zehnder interferometer.

12. The multiple optical frequency monitoring assembly of claim 1, wherein the beam splitter is a power splitter.

13. A multiple optical frequency monitoring assembly, comprising:
a first light source configured to generate a first light beam at a first optical frequency;
a second light source configured to generate a second light beam at a second optical frequency different from the first optical frequency;
combiner optics configured to combine the first light beam and the second light beam to generate a combined light beam;
an interferometer characterized by an initial frequency response and a complementary frequency response that is in anti-phase with the initial frequency response, wherein the interferometer is configured to receive the combined light beam, generate a first output light beam based on the combined light beam and the initial frequency response, and generate a second output light beam based on the combined light beam and the complementary frequency response,
wherein the first output light beam has first transmitted intensity corresponding to a first portion of the first light beam and a second transmitted intensity corresponding to a first portion of the second light beam,
wherein the second output light beam has third transmitted intensity corresponding to a second portion of the first light beam and a fourth transmitted intensity corresponding to a second portion of the second light beam, and
wherein the first transmitted intensity is based on the first optical frequency and the initial frequency response, the second transmitted intensity is based on the second optical frequency and the initial frequency response, the third transmitted intensity is based on the first optical frequency and the complementary frequency response, and the fourth transmitted intensity is based on the second optical frequency and the complementary frequency response;
filter optics configured to receive the first output light beam and the second output light beam, separate the first portion of the first light beam having the first transmitted intensity from the first portion of the second light beam having the second transmitted intensity, and separate the second portion of the first light beam having the third transmitted intensity from the second portion of the second light beam having the fourth transmitted intensity;
a detector arranged downstream from the filter optics, wherein the detector is configured to measure the first transmitted intensity, the second transmitted intensity, the third transmitted intensity, and the fourth transmitted intensity, generate a first ratio value representative of a first ratio between the first transmitted intensity and the third transmitted intensity, and generate a second ratio value representative of a second ratio between the second transmitted intensity and the fourth transmitted intensity; and
a controller configured to tune the first optical frequency of the first light source based on the first ratio value, and tune the second optical frequency of the second light source based on the second ratio value.

14. The multiple optical frequency monitoring assembly of claim 13, wherein the interferometer is a Mach-Zehnder interferometer comprising a first beam splitter and a second beam splitter,
wherein the first beam splitter and a second beam splitter are separated by a first path having a first path length and a second path having a second path length that differs from first path length by a path length difference,
wherein the path length difference defines a free spectral range of the initial frequency response and the complementary frequency response,
wherein the first beam splitter is configured to split the combined light beam into a first beam and a second beam,
wherein the first beam splitter is configured to direct the first beam along the first path and direct the second beam along the second path, and
wherein the second beam splitter is configured to receive the first beam and the second beam, generate the first output light beam based on a first combination of the first beam and the second beam, and generate the second output light beam based on a second combination of the first beam and the second beam.

15. The multiple optical frequency monitoring assembly of claim 13, wherein the initial frequency response comprises a first plurality of frequency ranges and a first plurality of resonant peak frequencies at which a transmittivity of the interferometer is at a maximum transmission level,
the complementary frequency response comprises a second plurality of frequency ranges and a second plurality of resonant peak frequencies at which the transmittivity of the interferometer is at the maximum transmission level, and
wherein the first optical frequency resides in a first frequency range of the first plurality of frequency ranges and the second optical frequency resides in a second frequency range of the first plurality of frequency ranges that is different from the first frequency range.

16. A multi-beam monitoring assembly, comprising:
a first light source configured to generate a first light beam with a beam property having a first property value;
a second light source configured to generate a second light beam with the beam property having a second property value different from the first property value;
combiner optics configured to combine the first light beam and the second light beam to generate a combined light beam;
a beam splitter configured to split the combined light beam into a monitored light beam, comprising a first portion of the first light beam and a first portion of the second light beam, and a reference light beam, comprising a second portion of the first light beam and a second portion of the second light beam;
an interferometer configured to receive the monitored light beam having a first incident intensity corresponding to the first portion of the first light beam and a second incident intensity corresponding to the first portion of the second light beam,
wherein the interferometer is characterized by a resonant frequency response comprising a plurality of frequency ranges and a plurality of resonant peak frequencies at which a transmittivity of the interferometer is at a maximum transmission level,
wherein the interferometer is configured to output the monitored light beam as a monitored output light beam according to the resonant frequency response,
wherein the monitored output light beam has first transmitted intensity corresponding to the first portion of the first light beam and a second transmitted intensity corresponding to the first portion of the second light beam,
wherein the first transmitted intensity is based on the first incident intensity, the first property value, and the resonant frequency response,
wherein the second transmitted intensity is based on the second incident intensity, the second property value, and the resonant frequency response;
filter optics configured to receive the monitored output light beam, and separate the first portion of the first light beam having the first transmitted intensity from the first portion of the second light beam having the second transmitted intensity,
wherein the filter optics are configured to receive the reference light beam, and separate the second portion of the first light beam having a first reference intensity from the second portion of the second light beam having a second reference intensity,
a detector arranged downstream from the filter optics, wherein the detector is configured to measure the first transmitted intensity, the second transmitted intensity, the first reference intensity, and the second reference intensity, generate a first difference value representative of a difference between the first transmitted intensity and the first reference intensity, and generate a second difference value representative of a difference between the second transmitted intensity and the second reference intensity; and
a controller configured to tune the first property value of the first light source based on the first difference value, and tune the second property value of the second light source based on the second difference value.

17. The multi-beam monitoring assembly of claim 16, wherein the beam property is an optical frequency.

18. The multi-beam monitoring assembly of claim 16, wherein the beam property is a linear polarization.

19. The multi-beam monitoring assembly of claim 18, wherein the first light beam and the second light beam have a same optical frequency.

20. The multi-beam monitoring assembly of claim 18, wherein the first property value corresponds to a first linear polarization and the second property value corresponds to a second linear polarization that is orthogonal to the first linear polarization.

21. The multi-beam monitoring assembly of claim 16, wherein the beam property is a spatial beam property.
